(19) United States
(12) Patent Application Publication
(10) Pub. No.: US 2006/0251797 A1
(43) Pub. Date: Nov. 9, 2006

(54) Device and method for applying a fluid medium to a substrate

(75) Inventors: Steffan Erfle, Tamm (DE); Juergen Goetz, Oberriexingen (DE); Thomas Gesang, Osterholz-Sharmbeck (DE)

Correspondence Address: KENYON & KENYON LLP, ONE BROADWAY, NEW YORK, NY, 10004, US

(73) Assignee: Robert Bosch GMBH, Stuttgart (DE)

(21) Appl. No.: 10/527,492

(22) PCT Filed: Mar. 28, 2003
(86) PCT No.: PCT/DE03/01035

§ 371 Date: Feb. 23, 2006

(30) Foreign Application Priority Data
Sep. 12, 2002 (DE) 102 42 410.1

(51) Int. Cl. C23C 16/52; B05C 11/00

(52) U.S. Cl. 427/8; 427/256; 118/712; 118/713; 118/300

(57) ABSTRACT

A device is described for applying a fluid medium to a substrate, having a capillary tube or a needle having one end, a first means using which the exit of the fluid medium from the end of the capillary tube or the adherence of the fluid medium to the end of the needle, in particular in the form of a droplet is detectable, and having further means using which the distance of the end of the capillary tube or the needle to the substrate can be changed. Furthermore, an image recording device and an image processing device associated therewith are provided, using which the point in time of the transfer of a droplet, located at the end of the capillary tube or the needle, from the capillary tube or the needle to the substrate is detectable when the distance of the end of the capillary tube or the needle to the substrate diminishes. Furthermore, a method which may be carried out in particular using this device for applying a fluid medium to a substrate is described, the point in time of the transfer of the fluid medium, exiting from the end of the capillary tube or adhering to the end of the needle, from the capillary tube to the substrate is detected by image processing without contact.

### FIELD OF THE INVENTION

The present invention relates to a device and a method for applying a fluid medium to a substrate as recited in the independent claims.

### BACKGROUND INFORMATION

In micrometering liquids such as adhesives, slurries, or pastes using a capillary tube or a needle, unevenness of the substrate onto which the liquid is to be dispensed results in considerable difficulties. Therefore, reproducible production of liquid dots of a uniform size on a substrate requires an identical distance between capillary tube and substrate when the liquid droplet exiting the capillary tube or suspended at its end is transferred to the substrate. If the distance of the capillary tube is excessive, there is no transfer, while if the distance between capillary tube and substrate is too small, no reproducible liquid volume is transferred. In addition, in this case there is the risk of contamination of the capillary tube, in particular of its outer side walls.

In general, it has been attempted to measure the distance between capillary tube and substrate for accurate and reliable metering to ensure uniform transfer of the liquid droplet from the capillary tube to the substrate. A distinction is usually made between “on-line” or at the process site and “off-line” or remote capillary distance measurement methods.

Off-line measurement methods include white light interferometry, for example. However, this measurement method implies a large measuring structure; therefore it may only be situated next to the dispensing needle or capillary tube used. Therefore, it is only suitable for measuring the distance of a mark or a sensor to the substrate, but not directly the distance between capillary tube and substrate or the time when a liquid droplet is transferred to the substrate. The measured value must therefore be used on site next to the capillary tube and a sensor must be moved toward the dispensing point where dispensing is to take place later. Both methods are subject to errors.

One example of “on-line” measurement at the process site is a measurement in which a distance feeler is used, which enters into contact with the substrate and thus ensures a well-defined distance between capillary tube and substrate. Such a feeler may, however, be used only with non-sensitive substrates. In addition, this is a contact measurement method, which is subject to a certain wear.

Another “on-line” measurement method at the process site is the laser triangulation method. In this case, measurement is carried out exactly at the dispensing site, but instead of the distance between the substrate and the capillary tube, the distance between the substrate and a laser triangulation sensor is measured. Therefore, this method is also an indirect method having the above-mentioned sources of measuring errors.

European Patent No. EP 214 100 A1 describes a needle distance measurement method in which a constant-pressure air jet is directed toward an object and exits from an axially movable nozzle body, which is adjusted to the surface of the object in such a way that the reaction force of the air flow on the nozzle body and therefore the distance between object and nozzle body is constant. Measuring the displacement path thus makes it possible to measure the distance. German Patent Application No. DE 198 398 30 A1 describes a method for highly accurate optical distance measurement by the principle of optical triangulation. German Patent Application No. DE 197 323 76 C1 describes a method and a device for distance measurement by the laser triangulation principle. In U.S. Pat. No. 5,507,872 a tactile feeler is used, a droplet transfer being measured via the deflection of a contact sensor in the dispenser. Finally, German Patent Application No. DE 197 48 317 C1 describes a method and a device for detecting the event of contact of a fluid medium with a surface using ultrasound. An ultrasound field is introduced into the medium to be dispensed and a change in the reflection response occurring upon contact of the fluid with the substrate is detected.

### SUMMARY

The method and device according to an example embodiment of the present invention for applying a fluid medium to a substrate may have the advantage that they are also suitable for sensitive substrates. Furthermore, considerably improved accuracy may be achieved by measuring at the process time, i.e., at the time of dispensing, and by measuring at the dispensing site, i.e., by directly detecting the point in time of transfer of the droplet onto the substrate at the point of transfer.

In addition, it may be advantageous that the transfer of the droplet from the capillary tube or the needle onto the substrate may be detected very rapidly, which makes the device and method according to the present invention particularly well-suited for on-line process control in mass production.

It is thus advantageous that well-proven individual components, i.e., image processing systems, which may be inexpensively adapted to the requirements of the individual case, may be used for implementing the image recording device and the image processing device. Furthermore, existing image processing software which is integrated in the image processing device and the computer provided therein may also be used.

It is furthermore advantageous that using two cameras, which detect the droplet both immediately before transfer and at the time of the transfer at different angles to the substrate, reliable detection of the transfer of the droplet to the substrate is possible even in the case of a relatively large substrate, on which there are additional components in the surroundings of the droplet transfer.

It is furthermore advantageous that a plurality of options adaptable to the requirements of the individual case is available for implementing the image recording device. Thus, the image may be recorded using a single camera, a plurality of cameras, or one camera having an associated rotatable mirror system; in the latter case, the rotatable mirror system is used in particular for detecting the droplet at different times or in different process phases at different angles to the substrate. In addition, the image recording device may also have an optical fiber, which is connected to a camera or a CCD chip, for example, making it unnecessary for the camera or the chip to be located near the site of droplet transfer onto the substrate.

It is furthermore advantageous that, using the device according to the present invention, a large number of fluid media such as adhesives, slurries, pastes, solutions, or suspensions may be applied to the substrate.

Finally, it is particularly advantageous if a microdispensing device, in particular in the form of a piston dispenser, is used for applying liquid droplets having a volume of 50 nL to 1 μL in the form of dots onto a substrate.

### BRIEF DESCRIPTION OF THE DRAWINGS

The present invention is elucidated in greater detail with reference to the figures in the description that follows.

FIG. 1a shows a schematic sketch of different phases when a capillary tube having a droplet approaches a substrate, an excessively small distance between capillary tube and substrate being reached.

FIG. 1b shows different process phases similar to FIG. 1a, but with an excessively large distance remaining between capillary tube and substrate.

FIG. 1c shows different process phases similar to FIG. 1a, with an excessively small distance remaining between capillary tube and substrate causing the liquid to be transferred to an outer wall of the capillary tube.

FIG. 2 shows an optimum transfer of the droplet to the substrate in different process phases.

FIG. 3a shows the detection of a meniscus height of a droplet before the transfer.

FIG. 3b shows a detection of the distance between capillary tube and substrate at the time of transfer of the droplet.

FIG. 4a shows the detection of the transfer of the droplet from the capillary tube to the substrate immediately before the transfer, using image processing.

FIG. 4b shows the detection of the droplet at the time of transfer using image processing.

FIG. 5a shows the detection of the droplet before the transfer using a camera and a rotatable mirror system.

FIG. 5b shows, in continuation of FIG. 5a, the detection of the droplet at the time of transfer.

FIG. 5c shows the detection of the droplet after being applied to the substrate.

FIG. 6 shows a schematic sketch of a measurement of a meniscus height using a reference marker.

FIGS. 7a and 7b show the detection of a transfer of a droplet onto a substrate from two different directions.

FIGS. 8a and 8b show the detection of the transfer of a droplet onto a substrate via the enclosed expanding surface is explained, while FIG. 9a shows different process phases when the droplet is transferred to the substrate, the meniscus width, i.e., the droplet width expanding at the time of the transfer.

FIG. 9b shows, in a work window, the detection of a surface when the droplet is transferred.

FIGS. 10a and 10b show the detection of a droplet of a capillary tube of a piston dispenser before the transfer onto the substrate and at the time of transfer onto the substrate, respectively.

FIGS. 11a and 11b show an alternative exemplary embodiment to that of FIGS. 10a and 10b for the dispensing device having a piston dispenser.

### DETAILED DESCRIPTION OF EXAMPLE EMBODIMENTS

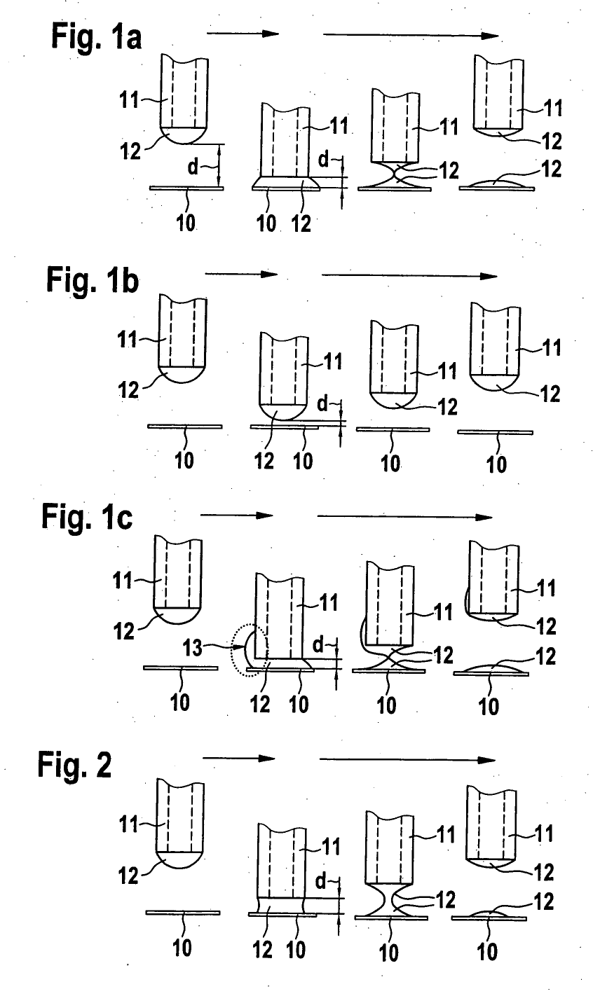

FIG. 1a shows different process phases in transferring a meniscus or droplet 12, which is situated at the end of a capillary tube 11, onto a flat substrate 10. The lower end of droplet 12 initially has a distance d to substrate 10, which gradually diminishes, until droplet 12 contacts substrate 10 and droplet 12 is transferred onto substrate 10. Subsequently, the distance between capillary tube 11 and substrate 10 increases again, and then a droplet 12 is caused to exit again from the end of capillary tube 11 to repeat another depositing of a droplet 12 onto substrate 10 at another location.

When droplet 12 is transferred to substrate 10 according to FIG. 1a, minimum distance d between capillary tube 11 and substrate 10 is too small; the shape of droplet 12 at the time of transfer, viewed spatially, may be approximately described as a spherical segment.

FIG. 1b explains a procedure similar to that in FIG. 1a, capillary tube 11 being brought insufficiently close to substrate 10; therefore, droplet 12 is not transferred onto substrate 10. In this case, minimum distance d between the lower end of droplet 12 and substrate 10 has proved to be too great.

FIG. 1c explains another scenario when droplet 12 is transferred to substrate 10, outer wall 13 of capillary tube 11 being contaminated due to excessively small minimum distance d between capillary tube 11 and substrate 10; therefore, no defined droplet volume is transferred to substrate 10, while the contamination of capillary tube 11 results in intolerable process inaccuracies when dispensing additional droplets 12.

One common feature of FIGS. 1a through 1c is that no reproducible volume of the fluid medium forming droplet 12 is transferred to substrate 10 due to the erroneous adjustment of minimum distance d between capillary tube 11 and substrate 10 taking into account the shape and size of droplet 12. The same considerations also apply for the case where capillary tube 11 is replaced by a needle at whose end droplet 12 adheres.

A reproducible production of uniformly sized dots on substrate 10 thus requires the detection of the time of transfer of a droplet 12 located at the end of capillary tube 11 or an appropriate needle from capillary tube 11 to substrate 10 as the distance of the end of capillary tube 11 or an appropriate needle to substrate 10 gradually diminishes.

In contrast, FIG. 2 shows an optimum scenario, in which droplet 12 is transferred to substrate 10 as capillary tube 11 initially approaches substrate 10. At the time of the transfer, droplet 12 has the shape of a catenoid when viewed spatially, i.e., it forms a column-like connection between capillary tube 11 and substrate 10. As soon as this phase is reached, the distance of capillary tube 11 to substrate 10 increases again, and a droplet 12 having a well-defined volume remains on substrate 10, while subsequently other droplets 12, also having well-defined volumes, may be applied to substrate 10 at other locations using capillary tube 11.

It is avoided in particular that droplet 12 is not transferred to substrate 10 at all as shown in FIG. 1b, or that capillary tube 11 comes so close to substrate 10 that the liquid medium gets onto an external area 13 of capillary tube 11, contaminating same.

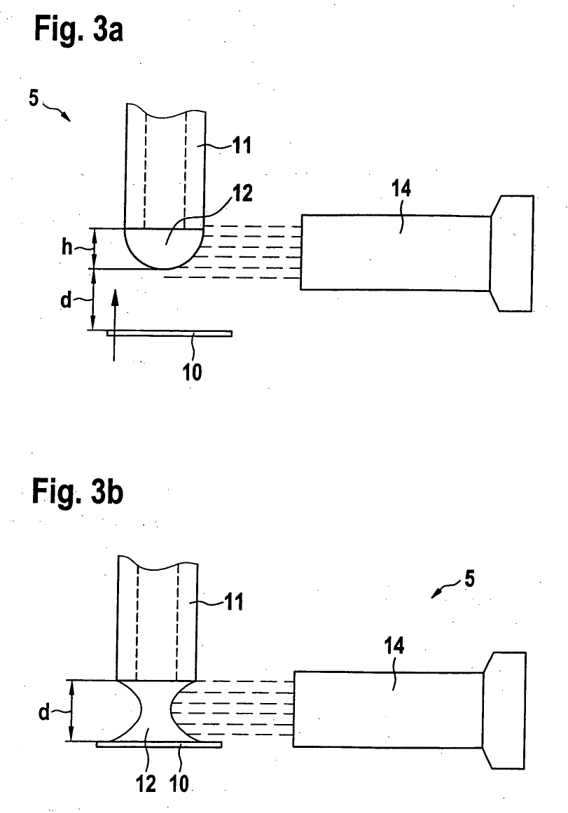

FIGS. 3a and 3b show the construction of a dispensing device 5, a droplet 12 shaped as a hemisphere and having height h being suspended initially at the end of capillary tube 11. Furthermore, using a first image recording device 14, for example, a camera or a CCD chip, which is associated with an image processing device (not shown) having a computer and an appropriate analyzing software, height h of droplet 12 is determined prior to the transfer of droplet 12 onto substrate 10, i.e., as they approach one another. Droplet 12, which has been recorded, is analyzed regarding its height and shape using the image processing device.

As capillary tube 11 further approaches substrate 10, the state shown in FIG. 3b occurs, i.e., a catenoid is formed as the fluid medium is transferred to substrate 10. This state is recognized using first image recording device 14 and it is used as the point in time when droplet 12 is transferred to substrate 10. Furthermore, using first image recording device 14 and the downstream image processing device, the distance between substrate 10 and capillary tube 11 is caused to increase immediately after the process phase of FIG. 3b is reached, resulting in an overall process sequence as shown in FIG. 2.

The procedure according to FIGS. 3a and 3b is therefore a contactless capillary distance measurement method at the site of dispensing and at the process time, the point in time when droplet 12 is transferred from capillary tube 11 to substrate 10 being recognized using image processing. Furthermore, the point in time when the droplet is transferred may also be measured after detecting height h of the droplet meniscus suspended at capillary tube 11 using image processing. The time when droplet 12 is transferred to substrate 10 is preferably detected using a camera as shown in FIG. 3b; however, it may also be determined using a light barrier, a fiber optic sensor, or a sound field directed at the meniscus, i.e., at droplet 12.

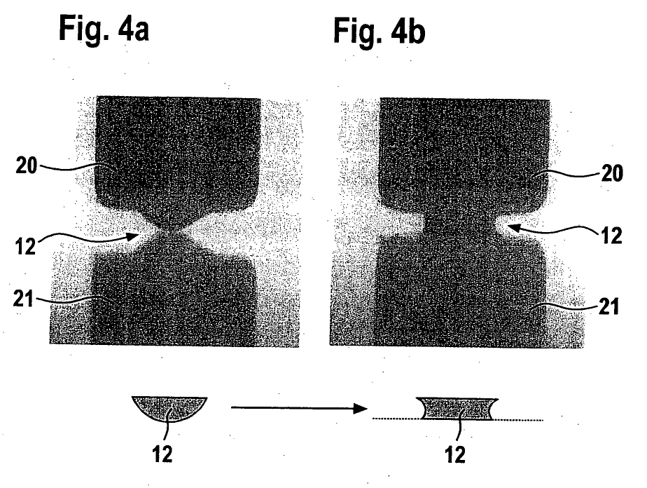

FIG. 4a shows two images of droplet 12 on substrate 10, before and at the time of the transfer, taken using an image processing device situated downstream from camera 14. A procedure known as “template matching” is used here, i.e., the change in shape of droplet 12 during the transfer is monitored. FIG. 4a shows first an original image 20 of capillary tube 11 and droplet 12 suspended at its end, as well as mirror image 21 of original image 20 reflected on reflective substrate 10. The image processing device thus detects both original image 20 and mirror image 21 using first camera 14. FIG. 4b shows how the cross section of droplet 12 changes from a circle segment (see FIG. 4a) to a catenoid. As soon as the point in time of the change in shape of droplet 12 from a suspended hemisphere to a catenoid in contact with substrate 10 and capillary tube 11 is reached and has been detected using the image processing device, the image processing device causes the distance between capillary tube 11 and substrate 10 to increase again; the process sequence of FIG. 2 is thus obtained. The “template matching” according to FIGS. 4a and 4b is very accurate. It has the disadvantage that considerable computing power must be provided in the image processing device.

A more rapid and usually sufficiently accurate method for recognizing the point in time when droplet 12 is transferred to substrate 10 may be implemented using a common differential image method with two consecutive images, for example, those according to FIGS. 4a and 4b, being subtracted from one another by the image processing device; if the resulting differential image exceeds a threshold value regarding its overall intensity, for example, a signal representing the state according to FIG. 4b is output by the image processing device. When this threshold value is reached, image recording device 14 and the downstream image processing device cause capillary tube 11 to stop approaching substrate 10 and the distance between capillary tube 11 and substrate 10 to increase again.

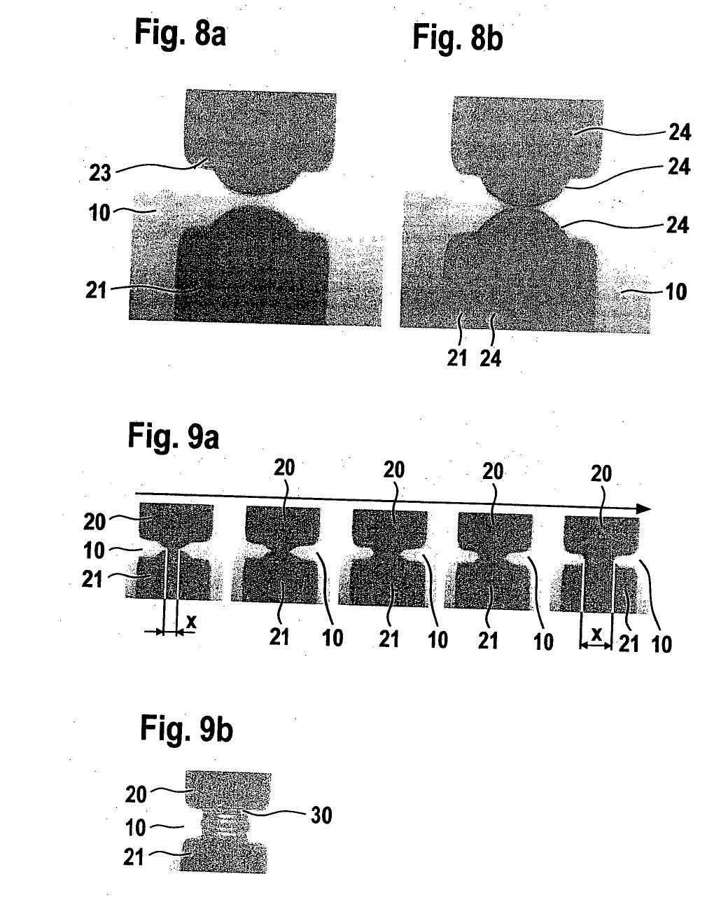

FIGS. 8a and 8b illustrate a third method for recognizing the point in time when droplet 12 is transferred to substrate 10. According to FIG. 8a, an original surface 23 formed by capillary tube 11 and droplet 12 suspended thereon is first calculated from an image similar to that of FIG. 4a. Furthermore, mirror image 21 of original surface 23, reflected on reflective substrate 10, is also shown in FIG. 8a and detected by an image recording device and the image processing device. As capillary tube 11 further approaches substrate 10, the state according to FIG. 8b sets in, i.e., original surface 23 and mirror surface 21 are connected to form a contiguous surface 24. This means that, when droplet 12 is transferred to substrate 10, original surface 23 increases suddenly to form contiguous surface 24. When this point in time is recognized by the image processing device, the device again causes capillary tube 11 to stop approaching substrate 10 and the distance between capillary tube 11 and substrate 10 to increase again.

The method according to FIGS. 8a and 8b has the advantage that capillary tube 11 together with droplet 12 may be represented prior to the transfer as a surface of individual pixels of the same intensity. This surface of uniform intensity, which may be formed as a full surface having dark pixels, for example, then increases suddenly when the state of FIG. 8b is reached. On the other hand, it is disadvantageous that the computation of suddenly increasing contiguous surface 24 is only applicable in the case of a reflective substrate 10.

FIG. 9a shows a fourth, alternative method for determining the point in time when droplet 12 is transferred to substrate 10. Also in this case, a reflective substrate 10 is assumed, an original image 20 and a mirror image 21 being detected. Furthermore, in the method according to FIG. 9a, in which capillary tube 11 gradually approaches substrate 10, a meniscus width x is determined, which first increases as capillary tube 11 descends. As soon as meniscus width x exceeds a preset threshold value, further approach of capillary tube 11 to substrate 10 is interrupted, and capillary tube 11 is raised again, which results overall in a procedure similar to the one of FIG. 2.

FIG. 9b illustrates a further method as an alternative to that of FIG. 9a, in which, to ensure an always constant meniscus width x, a surface is detected in a work window 30 or within a reference surface 30 of the image processing device using image recording device 14 and the associated image processing device. This work window is located in the area of the connecting surface between capillary tube 11 and droplet 12, i.e., the meniscus, at the time of the transfer. If the surface detected by the image processing device in work window 30 and assumed by droplet 12 exceeds a certain threshold value, the conclusion is drawn by the image processing device, similarly to the threshold value determined from the width of the meniscus in FIG. 9a, that capillary tube 11 has sufficiently approached substrate 10 and capillary tube 11 must now be raised. The embodiment of FIG. 9b differs from that of FIG. 9a only in that instead of a width x, a surface within a work window 30 is detected and compared to a threshold value.

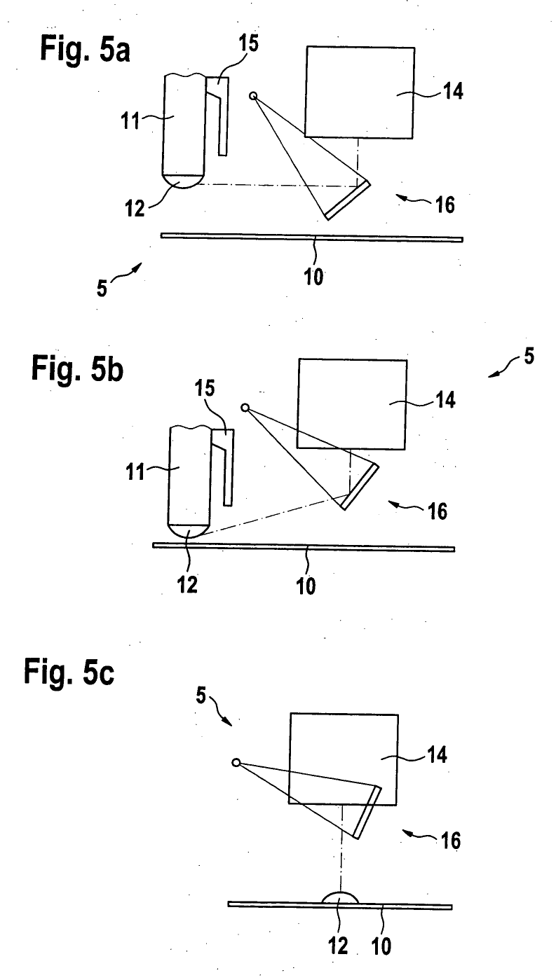

FIGS. 5a through 5c show an embodiment alternative to FIGS. 3a and 3b of a dispensing device 5. In this case, capillary tube 11 has a reference marker 15. Furthermore, a rotatable mirror system 16 is associated with first image recording device 14 in the form of a camera; droplet 10 suspended on capillary tube 11 is detectable under different angles to the substrate using this mirror system. In the position of rotatable mirror system 16 according to FIG. 5a, image recording device 14 first detects droplet 12 prior to its transfer to substrate 10, while in the position of rotatable mirror system 16 according to FIG. 5b, droplet 12 is detected at the time of its transfer to substrate 10. Only one image recording device 14 is needed here, which, in addition, is stationary. It is particularly advantageous if, within the scope of the above-described embodiment, the front face of capillary tube 11 is provided, at least partly, with an adhesive-repellent coating.

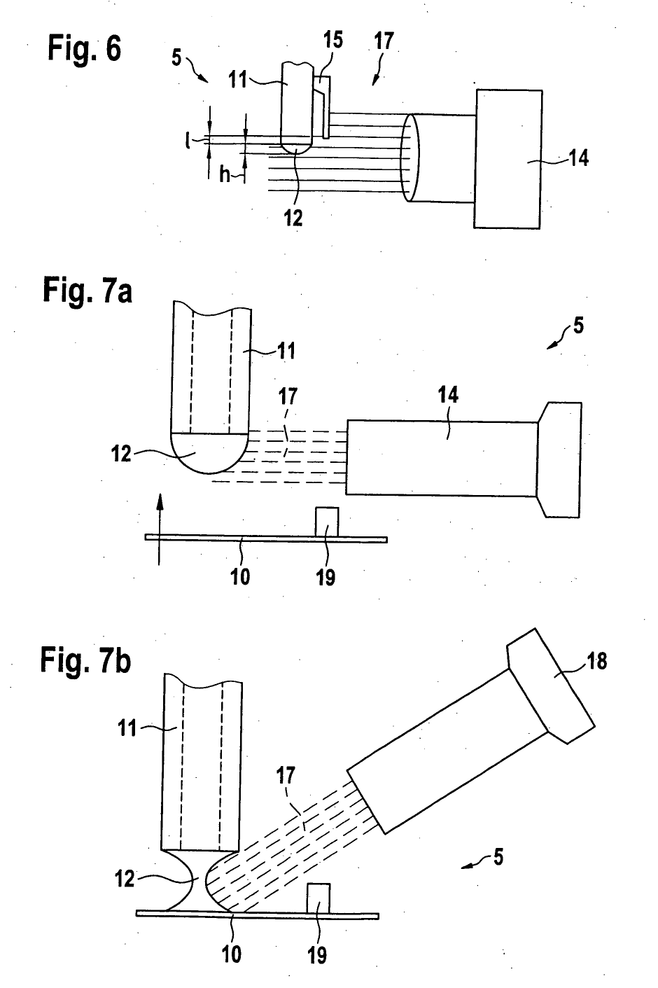

Reference marker 15 according to FIG. 5a, whose function is elucidated in detail with reference to FIG. 6, is mainly used for determining height h of droplet 12 suspended on the capillary tube. In this context, FIG. 5c further shows that, using rotatable mirror system 16 after droplet 12 is produced on substrate 10, a final quality control may also follow, for example, by measuring the geometry of droplet 12 in top view.

All in all, using a dispensing device 5 according to FIGS. 5a through 5c, not only the point in time of the transfer of droplet 12 to substrate 10 is detectable, but droplet 12 may also be optically measured prior to the transfer, and applied droplet 12 may be checked after the transfer.

FIG. 6 illustrates how the distance of reference marker 15 to the lower end of capillary tube 11, i.e., length l, is initially determined using first image recording device 14 and the downstream image processing device. Subsequently, the fluid medium is caused to exit the end of capillary tube 11 in the form of droplet 12, and the distance between reference marker 15 and the lower end of droplet 12 is determined using the first image recording device and the downstream image processing device. Height h of droplet 12 is determined from the difference of this measured value and previously determined length l.

The embodiment according to FIGS. 3a and 3b is mainly suitable for small flat substrates 10, in which the view of image recording device 14 is not obstructed by other components 19 surrounding the location where droplet 12 is to be applied to substrate 10 and thus capable of covering the lens of camera 14, for example.

A dispensing device 5, which is also suitable for large-surface substrates 10 having other components 19, is shown in FIGS. 7a and 7b. For this purpose, according to FIG. 7a the shape and height of droplet 12 are first measured using a first image recording device 14 in the form of a camera according to FIG. 3a. When capillary tube 11 subsequently approaches substrate 10 and droplet 12 is transferred to substrate 10, the point in time of this transfer is determined using a second image recording device 18, for example, a second camera. Second image recording device 18 illuminates substrate 10 obliquely from above, in such a way that its light beam 17 strikes substrate 10 obliquely and component 19 is not in the path of the beam.

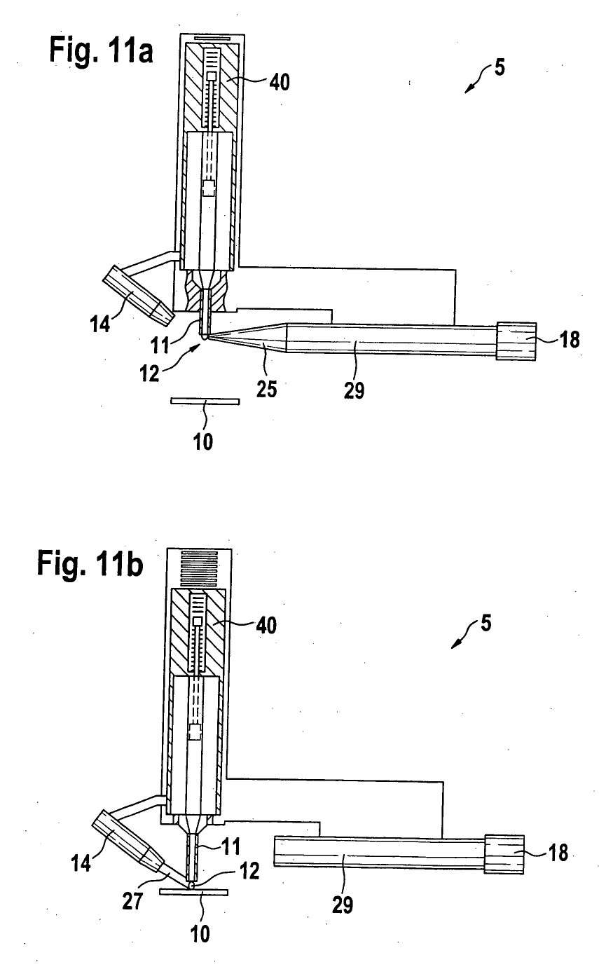

FIGS. 11a and 11b illustrate a further embodiment of a dispensing device, which in many respects is similar to the embodiment of FIGS. 7a and 7b. In particular, dispensing device 5 has a microdispensing device 40 in the form of a piston dispenser here, at whose lower end capillary tube 11 from which droplet 12 exits is located. Furthermore, the shape and/or height of droplet 12 is first detected prior to its transfer to substrate 10 using second image recording device 18 having a lens, for example, a telecentric lens 29. For this purpose, FIG. 11a shows a first illuminated area 25 illuminating droplet 12 and detected by second image recording device 18. Furthermore, according to FIG. 1a, an image processing device (not shown) is again located downstream from second image recording device 18. Furthermore, according to FIG. 11a, a first image recording device 14 in the form of a first camera is also provided, which is not active in this process phase.

As substrate 10 approaches dispensing device 40 according to FIG. 11a, which is indicated in FIGS. 3a and 7a by arrows, the state of FIG. 11b sets in, i.e., the point in time when droplet 12 is transferred to substrate 10. As elucidated above, this transfer is detected using first image recording device 14 and the image processing device associated therewith, first image recording device 14 causing a second area 27 to be illuminated where droplet 12 enters on being transferred to substrate 10.

The exemplary embodiment of FIGS. 11a and 11b is suitable in particular for large substrates, second camera 18 being set obliquely to substrate 10. The point in time when droplet 12 is transferred to substrate 10, is preferably detected by one of the image processing methods of FIGS. 4a, 4b or FIGS. 8a, 8b, or FIG. 9a or 9b.

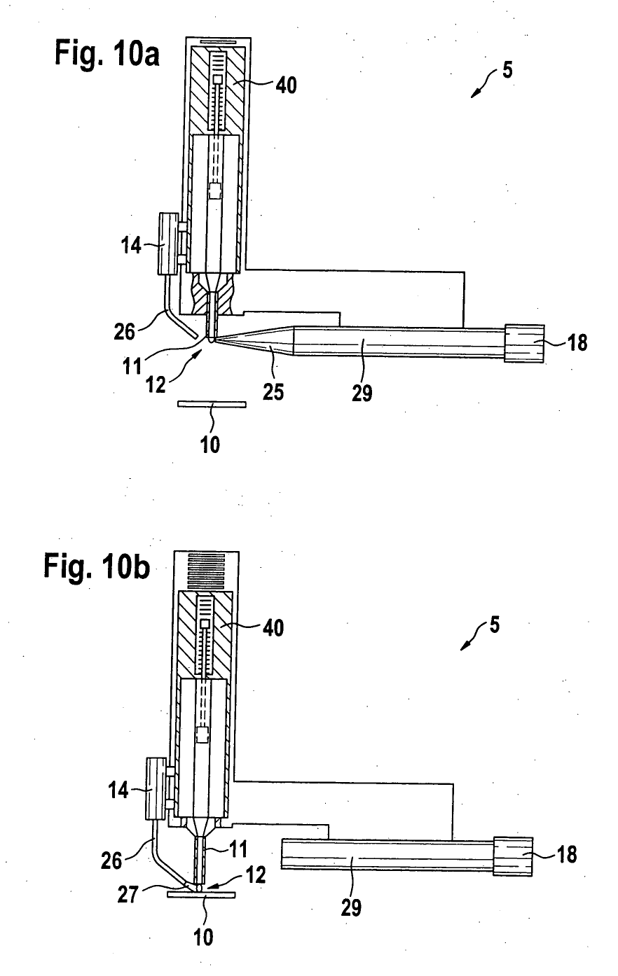

Finally, FIGS. 10a and 10b illustrate another exemplary embodiment alternative to that of FIGS. 11a and 11b, differing from the latter merely in that first image recording device 14 has an optical fiber 26, making it possible to locate image recording device 14 in a more flexible manner, which, however, is offset by the considerably worse transmission properties of optical fiber 26. On the other hand, in the embodiment of FIGS. 11a and 11b, as explained above, it is often only necessary to detect the point in time when droplet 12 is transferred to substrate 10.

1-17. (canceled)

18. A device for applying a fluid medium to a substrate, comprising:
a capillary tube or a needle having an end;
a first arrangement configured to one of: i) cause the fluid medium to exit from the end of the capillary tube in a form of a droplet, or ii) cause the fluid medium to adhere to the end of the needle in a form of a droplet;
a second arrangement configured to vary a distance of the end of the capillary tube or the needle to the substrate; and
at least one image recording device and at least one image processing device assigned to the at least one image recording device, a time of transfer of the droplet, from the capillary tube or the needle to the substrate being detected by the at least one image recording device when the distance of the end of the capillary tube or the needle to the substrate is reduced.

19. The device as recited in claim 18, wherein the image recording device and the image processing device are configured so that, immediately before the transfer of the droplet, a meniscus height or a shape of the droplet can be determined.

20. The device as recited in claim 19, wherein the image recording device and the image processing device are configured so that at least one of: i) contactless detection of the transfer of the droplet, and ii) immediately before the transfer, contactless determination of the meniscus height or the shape of the droplet, can be performed.

21. The device as recited in claim 18, wherein the image recording device includes at least one of: i) a camera, ii) a light barrier, ii) a fiber-optic sensor, and iv) an arrangement to detect or generate and detect a sound field.

22. The device as recited in claim 18, wherein the image recording device and the image processing device are configured so that the distance of the end of the capillary tube or the needle to the substrate or the distance of the droplet to the substrate can be detected.

23. The device as recited in claim 19, wherein the image recording device and the image processing device are configured so that a point in time when the droplet is transferred can be detected with the aid of a differential image method or by monitoring the shape change of the droplet when the droplet is transferred.

24. The device as recited in claim 18, wherein the substrate is reflective, and the image recording device and the image processing device are configured so that a point in time of the transfer of the droplet can be detected by determining a detected characteristic surface which changes at the time of the transfer.

25. The device as recited in claim 18, wherein the image recording device and the image processing device are configured so that, before the transfer, a first surface defined by at least a part of the droplet can be detected, and at the time of or after the transfer, a second surface defined by at least the part of the droplet and a mirror image of the droplet can be detected.

26. The device as recited in claim 25, wherein the image recording device and the image processing device are further configured so that a part of the capillary tube with needle can be detected.

27. The device as recited in claim 18, wherein the image recording device and the image processing device are configured so that a change in a width of the droplet or of a meniscus, beyond a threshold value, can be detected at the time of the transfer.

28. The device as recited in claim 18, wherein the image recording device and the image processing device are configured in such a way that a change in a surface in a work window beyond a threshold value, can be detected at the time of the transfer.

29. The device as recited in claim 18, wherein the image recording device has a camera and an associated rotatable mirror system, with the aid of which the droplet can be detected at different angles to the substrate.

30. The device as recited in claim 18, further comprising:
a reference marker connected to the capillary tube or the needle.

31. The device as recited in claim 18, wherein the image recording device has at least one optical fiber.

32. The device as recited in claim of 29, wherein the image recording device has two cameras which detect the droplet immediately before the transfer and detect the droplet at the time of the transfer at different angles to the substrate.

33. The device as recited in claim 18, wherein the capillary tube is part of a dispensing device.

34. The device as recited in claim 33, wherein the dispensing device is a piston dispense.

35. The device as recited in claim 18, wherein the image recording device includes a camera having a telecentric lens.

36. A method for applying a fluid medium to a substrate, comprising:
causing a fluid medium in the form of a droplet to one of exit a capillary at an end, or adhere to an end of a needle;
detecting, without contact, a time of transfer of the droplet to a substrate using image processing, when a distance from the end of the capillary tube or the needle to the substrate changes.
